(19) United States
(12) Patent Application Publication
(10) Pub. No.: US 2011/0048524 A1
(43) Pub. Date: Mar. 3, 2011

(54) THIN FILM SOLAR CELL AND METHOD OF MANUFACTURING THE SAME

(75) Inventors: Jung-Gyu NAM, Suwon-si (KR); Sang-Cheol PARK, Seoul (KR); Jin-Soo MUN, Geoje-si (KR); Yu-Hee KIM, Suwon-si (KR); Ji-Beom YOO, Seongnam-si (KR)

(73) Assignee: Samsung Electronics Co., Ltd., Suwon-si (KR)

(21) Appl. No.: 12/692,101

(22) Filed: Jan. 22, 2010

(30) Foreign Application Priority Data
Aug. 28, 2009 (KR) 10-2009-0080576

(51) Int. Cl. H01L 31/00; H01L 31/18

(52) U.S. Cl. 136/256; 438/72; 257/E31.12; 257/E31.128; 977/773

(57) ABSTRACT

A thin film solar cell, includes: a first electrode; a light absorption layer including a first light absorption layer including a group I element-group III element-group VI element compound, a second light absorption layer including a group I element-group III element-group VI element compound, and a third light absorption layer including a group I element-group III element-group VI element compound; and a second electrode, wherein the first light absorption layer has a band gap, which is less a band gap of the second light absorption layer, the band gap of the second light absorption layer is less than a band gap of the third light absorption layer, and the second light absorption layer has a band gap gradient, which increases in a direction from the first light absorption layer to the third light absorption layer.

This application claims priority to Korean Patent Application No. 10-2009-0080576, filed on Aug. 28, 2009, and all the benefits accruing therefrom under 35 U.S.C. §119, the content of which in its entirety is herein incorporated by reference.

### BACKGROUND OF THE INVENTION

1. Field of the Invention

This disclosure relates to a thin film solar cell and a method of manufacturing the same.

2. Description of the Related Art

A solar cell transforms solar energy into electrical energy. Basically, a solar cell is a diode including a PN junction.

Solar cells can be classified according to a material used in an optical absorption layer. A silicon solar cell includes silicon in a light absorption layer. A compound thin film solar cell includes a CuInGaSe₂ (“CIGS”), CuInSe₂ (“CIS”) or CuGaSe₂ (“CGS”) material in a light absorption layer. Other classes of solar cells include a group III-V solar cell, a dye-sensitized solar cell or an organic solar cell.

There has been much research to improve solar cell efficiency and solar cell method of manufacture. However, there remains a need for a solar cell having improved efficiency and a method of manufacturing the same.

### BRIEF SUMMARY OF THE INVENTION

Disclosed is a thin film solar cell having high efficiency. Also disclosed is a method of manufacturing a thin film solar cell having improved efficiency, safety and productivity.

Disclosed is a thin film solar cell including: a first electrode; a light absorption layer including a first light absorption layer including a group I element-group III element-group VI element compound, a second light absorption layer including a group I element-group III element-group VI element compound, and a third light absorption layer including a group I element-group III element-group VI element compound; and a second electrode, wherein the first light absorption layer has a band gap, which is less than a band gap of the second light absorption layer, the band gap of the second light absorption layer is less than a band gap of the third light absorption layer, and the second light absorption layer has a band gap gradient, which increases in a direction from the first light absorption layer to the third light absorption layer.

The first light absorption layer, the second light absorption layer, and the third light absorption layer may each independently have a band gap of about 1 electron volt to about 3 electron volts.

Also disclosed is a method for manufacturing a thin film solar cell. The method includes forming a plurality of particle layers, each layer including nanoparticles, the nanoparticles including one selected from the group consisting of a group I element, a group III element, a group VI element, alloys thereof and a combination thereof; forming a light absorption precursor layer by sequentially disposing the particle layers; and heat treating the light absorption precursor layer to form a light absorption layer.

The band gap of the nanoparticles of each particle layer may be different, and the band gaps of the particle layers may increase according to a stacking sequence of the particle layers.

The light absorption layer may include: a first light absorption layer including a group I element-group III element-group VI element compound; a second light absorption layer including a group I element-group III element-group VI element compound; and a third light absorption layer including a group I element-group III element-group VI element compound, and the first light absorption layer may have a band gap, which is less than a band gap of the second light absorption layer, the second light absorption layer may have a band gap, which is less than a band gap of the third light absorption layer, and the second light absorption layer may have a band gap gradient, which increases in a direction from the first light absorption layer to the third light absorption layer.

The nanoparticles may have an average particle diameter of about 2 nanometers to about 500 nanometers.

The particle layers may have a thickness of about 0.1 micrometer to about 5 micrometers.

The heat treatment may be performed at a temperature of about 200 degrees Celsius to about 700 degrees Celsius.

The first light absorption layer may have a thickness of about 0.1 micrometer to about 0.8 micrometer, the second light absorption layer may have a thickness of about 0.3 micrometer to about 2 micrometers and the third light absorption layer may have a thickness of about 0.1 micrometer to about 0.8 micrometer. A light absorption layer including the first light absorption layer, the second light absorption layer, and the third light absorption layer may have a thickness of about 0.1 micrometer to about 5 micrometers.

The group I element may be copper, the group III element may be aluminum, gallium or indium, and the group VI element may be sulfur, selenium or tellurium.

The first light absorption layer may be on the second light absorption layer and the second light absorption layer may be on the third light absorption layer, and the first light absorption layer, the second light absorption layer and the third light absorption layer may have a composition of CuInSe₂/CuIn(Se₁₋ₓSₓ)₂/CuInS₂, wherein 0<x<1, CuInS₂/Cu(In_{1-y}Ga_{y})S₂/CuGaS₂, wherein 0<y<1, CuGaSe₂/CuGa(Se₁₋ₓSₓ)₂/CuGaS₂, wherein 0<x<1, CuInSe₂/Cu(In_{1-y}Ga_{y})Se₂/CuGaSe₂, wherein 0<y<1, or CuInSe₂/Cu(In_{1-y}Ga_{y})(Se₁₋ₓSₓ)₂/CuGaS₂, wherein 0<x<1, and 0<y<1, respectively.

Other aspects of this disclosure will be further described in the following detailed description

The thin film solar cell has excellent photoelectric conversion efficiency and the method of manufacturing the same has good productivity and safety.

### BRIEF DESCRIPTION OF THE DRAWINGS

The above and other aspects, advantages and features of this disclosure will become more apparent by describing in further detail exemplary embodiments thereof with reference to the accompanying drawings, in which:

FIG. 1 is a schematic cross-sectional view of an exemplary embodiment of a thin film solar cell;

FIG. 2 is a flow chart showing an exemplary embodiment of a process of manufacturing a light absorption layer; and

FIGS. 3A and 3B are cross-sectional views showing an exemplary embodiment of a sequential process of manufacturing a light absorption layer.

### DETAILED DESCRIPTION OF THE INVENTION

The present disclosure will be described more fully hereinafter with reference to the accompanying drawings, in which exemplary embodiments of this disclosure are shown. As those skilled in the art would realize, the described embodiments may be modified in various different ways, all without departing from the spirit or scope of this disclosure.

In the drawings, the thickness of layers, films, panels, regions, etc., are exaggerated for clarity. Like reference numerals designate like elements throughout the specification. It will be understood that when an element such as a layer, film or substrate is referred to as being “on” another element, it may be directly on the other element or intervening elements may also be present.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting. As used herein, the terms “a” and “an” are open terms that may be used in conjunction with singular items or with plural items, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

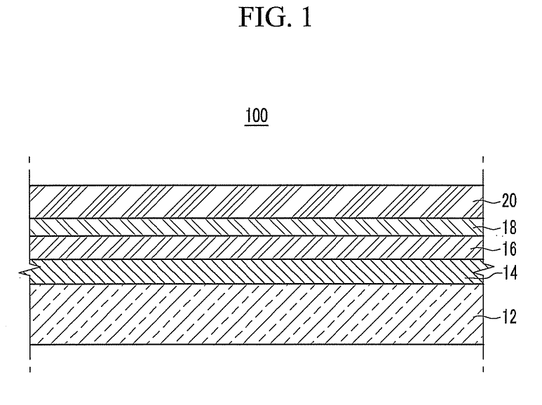

FIG. 1 is a schematic cross-sectional view of an exemplary embodiment of a thin film solar cell.

Referring to FIG. 1, the thin film solar cell 100 includes a substrate 12, a rear electrode 14, a light absorption layer 16, a buffer layer 18 and a front electrode 20. In an embodiment, the thin film solar cell 100 is a substrate type thin film solar cell. As shown in FIG. 1, the buffer layer 18 is disposed between the light absorption layer 16 and the front electrode 20. In another embodiment the buffer layer 18 may be omitted.

The substrate 12 may comprise a rigid material or a flexible material. In an embodiment, the substrate 12 may comprise glass, quartz, silicon, a synthetic resin, a polymer, a metal, or the like or a combination thereof. In another embodiment, the substrate may include a glass plate, a quartz plate, a silicon plate, a synthetic resin plate, a metal plate, or the like or a combination thereof. Examples of the synthetic resin include polyethylene naphthalate (“PEN”), polyethylene terephthalate (“PET”), polycarbonate, polyvinyl alcohol, polyacrylate, polyimide, polynorbornene, polyethersulfone (“PES”), or the like or a combination thereof. Exemplary metals include stainless steel, aluminum, or the like or a combination thereof. In an embodiment, the metal plate may include a stainless steel foil, an aluminum foil, or the like or a combination thereof.

The rear electrode 14 may include molybdenum, aluminum, silver, gold, platinum, nickel, copper, or the like or a combination thereof. The rear electrode 14 may be formed (e.g., disposed) by sputtering, vacuum deposition, or the like or a combination thereof.

The front electrode 20 may be transparent, thus may transmit incident solar light, and includes a transparent electrically conductive material. Generally, a transparent conductive oxide (“TCO”), which is sufficiently transparent, is sufficiently electrically conductive and has a sufficiently smooth surface (e.g., fine surface roughness), can be used. Exemplary transparent conductive oxides include ZnO:Al, ZnO:B, SnO₂, SnO₂:F, indium tin oxide (“ITO”), or the like or a combination thereof.

The buffer layer 18 may be disposed between the light absorption layer 16 and the front electrode 20. The buffer layer 18 alleviates a work function difference and a lattice constant difference between the light absorption layer 16 and the front electrode 20. The buffer layer 18 may include an n-type semiconductor. The n-type semiconductor may include CdS, ZnS, In₂O₃, or the like or a combination thereof. The buffer layer 18 may be formed (e.g., disposed) by a method comprising a sputtering process, a sol-gel process, a pyrolysis process, a spray pyrolysis process or the like.

In another embodiment, the thin film solar cell may be a superstrate type thin film solar cell. The superstrate-type thin film solar cell includes a light absorption layer disposed on the rear electrode, and the front electrode and the substrate disposed on the light absorption layer.

The light absorption layer 16 absorbs light, forms electron-hole pairs and transfers the electrons and holes to the front and rear electrodes, respectively, to thereby cause electric current to flow.

The light absorption layer 16 includes a first, a second and a third light absorption layer. The first light absorption layer includes a group I element-group III element-group VI element (e.g., group I-III-VI) compound; the second light absorption layer includes a group I element-group III element-group VI element (e.g., group I-III-VI) compound; and the third light absorption layer includes a group I element-group III element-group VI element (e.g., group I-III-VI) compound. The band gap of the first light absorption layer may be less than a band gap of the second light absorption layer, the band gap of the second light absorption layer is less than a band gap of the third light absorption layer, and the second light absorption layer has a band gap gradient. Thus the band gap of the second light absorption layer forms a gradient, and the band gap of the second light absorption layer may increase in a direction from the first light absorption layer to the third light absorption layer. Thus the light absorption layer 16 comprises layers having a plurality of band gaps. Also, while not wanting to be bound by theory, it is understood that the disclosed light absorption layer 16 may increase the amount of photoelectric current and improve photoelectric conversion efficiency.

The first light absorption layer, the second light absorption layer, and the third light absorption layer may each comprise a compound semiconductor including a group I element-group III element-group IV element (e.g., group I-III-VI) compound.

The first light absorption layer may have a band gap of about 1 electron volt (“eV”) to about 3 eV, specifically about 1 eV to about 1.7 eV, more specifically about 1 eV to about 1.4 eV. The second light absorption layer may have a band gap of about 1 eV to about 3 eV, specifically from about 1 eV to about 2 eV, more specifically from about 1 eV to about 1.5 eV. The third light absorption layer may have a band gap of about 1 eV to about 3 eV, specifically from about 1.2 eV to about 2.5 eV, more specifically from about 1.4 eV to about 2 eV.

The first light absorption layer may have a thickness of about 0.1 micrometer (“μm”) to about 0.8 μm, specifically from about 0.2 μm to about 0.7 μm, more specifically from about 0.3 μm to about 0.6 μm. The second light absorption layer may have a thickness of about 0.3 μm to about 2 μm, specifically from about 0.5 μm to about 1.8 μm, more specifically from about 0.8 μm to about 1.5 μm. The third light absorption layer may have a thickness of about 0.1 μm to about 0.8 μm, specifically from about 0.2 μm to about 0.7 μm, more specifically from about 0.3 μm to about 0.6 μm. The first light absorption layer, the second light absorption layer, and the third light absorption layer may have a thickness selected to minimize optical loss in the light absorption layer and improve photoelectric conversion efficiency.

The light absorption layer, which includes the first light absorption layer, the second light absorption layer and the third light absorption layer, may have a thickness of about 0.1 μm to about 5 μm, specifically from about 0.3 μm to about 5 μm, more specifically about 0.5 to about 3 μm. When the light absorption layer has a thickness of the above range, the light loss in the light absorption layer is minimized, thereby improving the photoelectric conversion efficiency.

The group I element may comprise copper, the group III element may comprise aluminum, gallium or indium, and the group VI element may comprise sulfur, selenium, or tellurium.

In an embodiment, the first light absorption layer may comprise CuInSe₂, CuInS₂, or CuGaSe₂ or the like or a combination thereof. In an embodiment the second light absorption layer may comprise CuIn(Se₁₋ₓSₓ)₂, wherein 0<x<1, Cu(In_{1-y}Ga_{y})S₂, wherein 0<y<1, CuGa(Se₁₋ₓSₓ)₂, wherein 0<x<1, Cu(In_{1-y}Ga_{y})Se₂, wherein 0<y<1, Cu(In_{1-y}Ga_{y})(Se₁₋ₓSₓ)₂, wherein 0<x<1 and 0<y<1, or the like or a combination thereof. In an embodiment, the third light absorption layer may comprise CuInS₂, CuGaS₂, CuGaSe₂, or the like or a combination thereof.

In an embodiment, the first light absorption layer may be on the second light absorption layer, the second light absorption layer may be on the third light absorption layer, and the first light absorption layer, the second light absorption layer and the third light absorption layer may have a composition selected from CuInSe₂/CuIn(Se₁₋ₓSₓ)₂/CuInS₂ (0<x<1), CuInS₂/Cu(In_{1-y}Ga_{y})S₂/CuGaS₂ (0<y<1), CuGaSe₂/CuGa(Se₁₋ₓSₓ)₂/CuGaS₂ (0<x<1), CuInSe₂/Cu(In_{1-y}Ga_{y})Se₂/CuGaSe₂ (0<y<1), or CuInSe₂/Cu(In_{1-y}Ga_{y})(Se₁₋ₓSₓ)₂/CuGaS₂ (0<x<1, 0<y<1), respectively, wherein the virgule distinguishes the first, the second and the third light absorption layers. When the first light absorption layer, the second light absorption layer, and the third light absorption layer have the above compositions, the light absorption layer including them may have a band gap gradient (e.g., divided band gaps) and have improved photoelectric conversion efficiency.

While not wanting to be bound by theory, it is understood that the light absorption layer having a band gap gradient provides a thin film solar cell having excellent photoelectric current and improved photoelectric conversion efficiency.

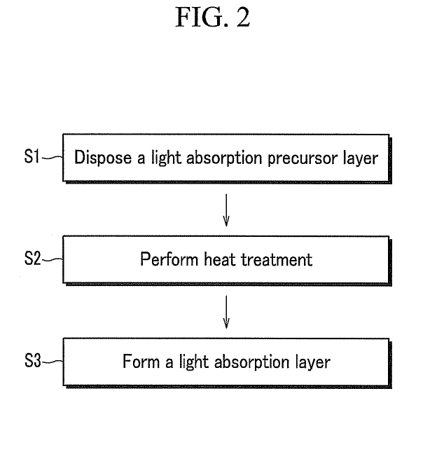

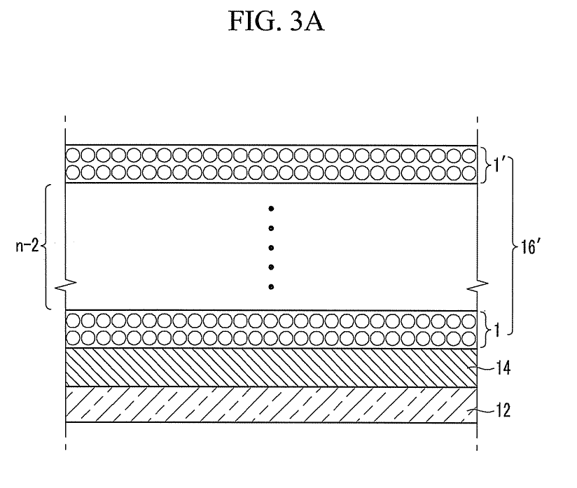

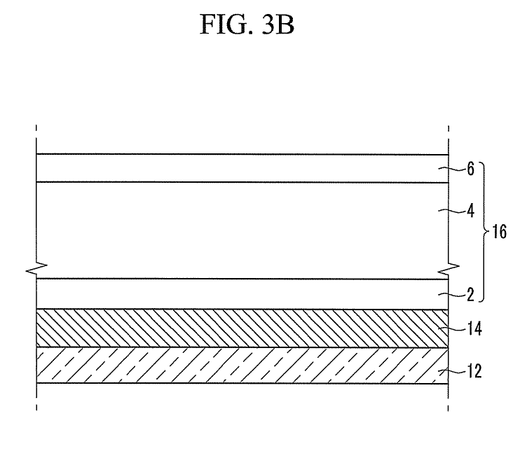

Hereafter, a method for manufacturing a thin film solar cell will be described with reference to FIGS. 2, 3A and 3B.

FIGS. 2, 3A and 3B show a process of manufacturing a light absorption layer according to one embodiment. First, in operation S1, a rear electrode 14 is formed (e.g., disposed) on a substrate 12, and a light absorption precursor layer 16′ is formed (e.g. disposed) on the rear electrode 14.

Referring to FIG. 3A, the light absorption precursor layer 16′ may be formed (e.g., disposed) by stacking (e.g. sequentially disposing) a quantity of n particle layers, including a first particle layer 1 and a n^{th} particle layer 1′, each particle layer including a plurality of nanoparticles, the nanoparticles comprising an element selected from the group consisting of a group I element, a group III element, a group VI element, alloys thereof, and the like and a combination thereof. Herein, n is an integer, which is equal to or greater than 2, and may be selected based on the thickness of a photoactive layer. The composition of the first and n^{th} particle layers 1 and 1′, respectively, which may be stacked, may be the same or different.

Since nanoparticles are used to form the particle layers, the material utility efficiency may be increased. Also, when different kinds of nanoparticles are combined, the mixing ratio of the nanoparticles may be easily controlled and a particle layer of a desired composition may be efficiently formed.

Each of the particle layers, including first and n^{th} particle layers 1 and 1′, may be formed (e.g. disposed) by dispersing nanoparticles selected from the group consisting of a group I element, a group III element, a group VI element, alloys thereof, and combination thereof in an organic solvent to thereby prepare an ink-type solution, and coating the surface of the rear electrode 14 with the solution by a method comprising spin coating, slit coating, printing, drop casting, or a dip coating to form a coated electrode, and drying the coated electrode.

The nanoparticles of each particle layer may include Cu particles, Al particles, Ga particles, In particles, S particles, Se particles, Te particles, Cu—S alloy particles, Cu—Se alloy particles, Cu—Te alloy particles, Al—S alloy particles, Al—Se alloy particles, Al—Te alloy particles, Ga—S alloy particles, Ga—Se alloy particles, Ga—Te alloy particles, In—S alloy particles, In—Se alloy particles, In—Te alloy particles, Cu—Al—S alloy particles, Cu—Al—Se alloy particles, Cu—Al—Te alloy particles, Cu—Ga—S alloy particles, Cu—Ga—Se alloy particles, Cu—Ga—Te alloy particles, Cu—In—S alloy particles, Cu—In—Se alloy particles, Cu—In—Te alloy particles, Cu—Al—Ga—S alloy particles, Cu—Al—Ga—Se alloy particles, Cu—Al—Ga—Te alloy particles, Cu—Al—In—S alloy particles, Cu—Al—In—Se alloy particles, Cu—Al—In—Te alloy particles, Cu—Ga—In—S alloy particles, Cu—Ga—In—Se alloy particles, Cu—Ga—In—Te alloy particles, Cu—Al—S—Se alloy particles, Cu—Al—Se—Te alloy particles, Cu—Al—S—Te alloy particles, Cu—Ga—S—Se alloy particles, Cu—Ga—Se—Te alloy particles, a Cu—Ga—S—Te alloy particles, Cu—In—S—Se alloy particles, Cu—In—Se—Te alloy particles, Cu—In—S—Te alloy particles, Cu—Al—Ga—S—Se alloy particles, Cu—Al—Ga—Se—Te alloy particles, Cu—Al—Ga—S—Te alloy particles, Cu—Al—In—S—Se alloy particles, Cu—Al—In—Se—Te alloy particles, Cu—Al—In—S—Te alloy particles, Cu—Ga—In—S—Se alloy particles, Cu—Ga—In—Se—Te alloy particles, Cu—Ga—In—S—Te alloy particles, or the like or combination thereof, but are not limited thereto.

For example, a light absorption precursor layer may be formed by forming (e.g. disposing) a first particle layer comprising Cu—In—Se alloy nanoparticles, and forming (e.g. disposing) a second particle layer comprising Cu—In—S alloy nanoparticles on the first particle layer. The light absorption precursor layer may be formed by forming (e.g. disposing) a first particle layer comprising a mixture of Cu—Se alloy nanoparticles and In—Se alloy nanoparticles, forming (e.g. disposing) a second particle layer comprising a mixture of Cu—Se alloy nanoparticles and In—S alloy nanoparticles on the first particle layer, and forming (e.g. disposing) a third particle layer comprising a mixture of Cu nanoparticles and In—S alloy nanoparticles on the second particle layer. Also, the light absorption precursor layer may be formed by forming (e.g. disposing) a first particle layer of Cu—In—Se alloy nanoparticles, forming (e.g. disposing) a second particle layer of Cu—In—Se—S alloy nanoparticles on the first particle layer, and forming (e.g. disposing) a third particle layer of Cu—In—S alloy nanoparticles on the second particle layer.

The nanoparticles may have an average particle diameter of about 2 nanometers (nm) to about 500 nm, specifically about 2 nm to about 200 nm, more specifically from about 2 nm to about 100 nm. When the nanoparticles have an average particle diameter of the foregoing range, a substitution reaction between the elements on the interface between the particle layers in a subsequent heat treatment is readily performed and crystallization is improved. Therefore, a light absorption layer having excellent photoelectric conversion efficiency may be efficiently formed to have a band gap gradient.

Each particle layer may have a thickness of about 0.1 μm to about 5 μm, specifically about 0.3 μm to about 4 μm, more specifically about 0.5 μm to about 3 μm. When the particle layers have a thickness of the above range, it is understood that a substitution reaction among the elements readily occurs on the interface between the particle layers in a subsequent heat treatment. Thus, a light absorption layer having a band gap gradient is efficiently formed and formation of a void in the light absorption layer may be substantially reduced or effectively prevented.

Subsequently, in operations S2 and S3, a light absorption layer is formed (e.g. disposed) by heat treating the light absorption precursor layer. While not wanting to be bound by theory, it is understood that as the light absorption precursor layer is heat treated, the elements melt and diffuse at the interface between the particle layers to thereby cause a reaction, e.g., a substitution reaction, forming a light absorption layer having a band gap gradient.

Referring to FIG. 3B, a light absorption layer 16 including the first light absorption layer 2, the second light absorption layer 4 and the third light absorption layer 6 may be formed (e.g. disposed). The first light absorption layer 2 has a band gap, which is less than the band gap of the second light absorption layer 4, and the second light absorption layer 4 has a band gap, which is less than the band gap of the third light absorption layer 6. The second light absorption layer 4 has a band gap gradient, which increases in a direction towards (e.g. closer to) the third light absorption layer 6. As a result, the light absorption layer 16 has a band gap gradient, increasing an amount of a photoelectric current and improving the photoelectric conversion efficiency.

The heat treatment may be performed at a temperature of about 200° C. to about 700° C., specifically about 300° C. to about 600° C., more specifically from about 400° C. to about 570° C., for about 5 minutes to about 2 hours, specifically from about 10 minutes to about 1 hour, more specifically from about 10 minutes to about 50 minutes. When the heat treatment is performed according to the above conditions, all or a portion of the constituent elements melt and react with each other sufficiently, thereby efficiently forming a light absorption layer having a band gap gradient. Also, the heat treatment may be performed in an atmosphere of air, nitrogen, argon, helium, or the like or combination thereof. In an embodiment, the heat treatment may be performed in an inert atmosphere. The inert atmosphere may include nitrogen, or argon or the like, but is not limited thereto.

When a light absorption layer is formed by sequentially stacking a plurality of particle layers and heat treating the particle layers, a light absorption layer with having a band gap gradient may be efficiently formed. Also, because a toxic gas, such as hydrogen selenide is not used, a highly efficient thin film solar cell may be mass-produced.

While this disclosure has been described in connection with exemplary embodiments, it is to be understood that the invention is not limited to the disclosed embodiments, but, on the contrary, is intended to cover various modifications and equivalent arrangements included within the spirit and scope of the appended claims.

What is claimed is:

1. A thin film solar cell, comprising:
a first electrode;
a light absorption layer comprising
a first light absorption layer comprising a group I element-group III element-group VI element compound,
a second light absorption layer comprising a group I element-group III element-group VI element compound, and
a third light absorption layer comprising a group I element-group III element-group VI element compound; and
a second electrode,
wherein the first light absorption layer has a band gap, which is less than a band gap of the second light absorption layer, the band gap of the second light absorption layer is less than a band gap of the third light absorption layer, and the second light absorption layer has a band gap gradient, which increases in a direction from the first light absorption layer to the third light absorption layer.

2. The thin film solar cell of claim 1, wherein the first light absorption layer, the second light absorption layer and the third light absorption layer each independently have a band gap of about 1 electron-volt to about 3 electron-volts.

3. The thin film solar cell of claim 1, wherein the first light absorption layer has a thickness of about 0.1 micrometer to about 0.8 micrometer,
the second light absorption layer has a thickness of about 0.3 micrometer to about 2 micrometers, and
the third light absorption layer has a thickness of about 0.1 micrometer to about 0.8 micrometer.

4. The thin film solar cell of claim 1, wherein the light absorption layer comprising the first light absorption layer, the second light absorption layer and the third light absorption layer has a thickness of about 0.1 micrometer to about 5 micrometers.

5. The thin film solar cell of claim 1, wherein the group I element is copper, the group III element is aluminum, gallium or indium, and the group VI element is sulfur, selenium or tellurium.

6. The thin film solar cell of claim 1, wherein the first light absorption layer is on the second light absorption layer and the second light absorption layer is on the third light absorption layer, and the first light absorption layer, the second light absorption layer and the third light absorption layer have a composition of CuInSe₂/CuIn(Se₁₋ₓSₓ)₂/CuInS₂, wherein 0<x<1, CuInS₂/Cu(In_{1-y}Ga_{y})S₂/CuGaS₂, wherein 0<y<1, CuGaSe₂/CuGa(Se₁₋ₓSₓ)₂/CuGaS₂, wherein 0<x<1,CuInSe₂/Cu(In_{1-y}Ga_{y})Se₂/CuGaSe₂, wherein 0<y<1, or CuInSe₂/Cu(In_{1-y}Ga_{y})(Se₁₋ₓSₓ)₂/CuGaS₂, wherein 0<x<1 and 0<y<1, respectively.

7. A method for manufacturing a thin film solar cell, the method comprising:
forming a plurality of particle layers, each layer including nanoparticles, the nanoparticles comprising one selected from the group consisting of a group I element, a group III element, a group VI element, alloys thereof and a combination thereof;
forming a light absorption precursor layer by sequentially disposing the particle layers; and
heat treating the light absorption precursor layer to form a light absorption layer.

8. The method of claim 7, wherein a band gap of the nanoparticles of each particle layer is different, and the band gaps of the particle layers increase according to a stacking sequence of the particle layers.

9. The method of claim 8, wherein the light absorption layer includes a first light absorption layer including a group I element-group III element-group VI element compound; a second light absorption layer including a group I element-group III element-group VI element compound; and a third light absorption layer including group I element-group III element-group VI element compound, and
the first light absorption layer has a band gap, which is less than a band gap of the second light absorption layer, the second light absorption layer has a band gap, which is less than a band gap of the third light absorption layer, and the second light absorption layer has a band gap gradient, which increases in a direction from the first light absorption layer to the third light absorption layer.

10. The method of claim 9, wherein the first light absorption layer has a thickness of about 0.1 micrometer to about 0.8 micrometer,
the second light absorption layer has a thickness of about 0.3 micrometer to about 2 micrometers,
and the third light absorption layer has a thickness of about 0.1 micrometer to about 0.8 micrometer.

11. The method of claim 9, wherein the first light absorption layer is on the second light absorption layer and the second light absorption layer is on the third light absorption layer, and the first light absorption layer, the second light absorption layer and the third light absorption layer have a composition of CuInSe₂/CuIn(Se₁₋ₓSₓ)₂/CuInS₂, wherein 0<x<1, CuInS₂/Cu(In_{1-y}Ga_{y})S₂/CuGaS₂, wherein 0<y<1, CuGaSe₂/CuGa(Se₁₋ₓSₓ)₂/CuGaS₂, wherein 0<x<1,CuInSe₂/Cu(In_{1-y}Ga_{y})Se₂/CuGaSe₂, wherein 0<y<1, or CuInSe₂/Cu(In_{1-y}Ga_{y})(Se₁₋ₓSₓ)₂/CuGaS₂, wherein 0<x<1, 0<y<1, respectively.

12. The method of claim 7, wherein the nanoparticles have an average particle diameter of about 2 nanometers to about 500 nanometers.

13. The method of claim 7, wherein the particle layers have a thickness of about 0.1 micrometer to about 5 micrometers.

14. The method of claim 7, wherein the heat treatment is performed at a temperature of about 200 degrees Celsius to about 700 degrees Celsius.

15. The method of claim 7, wherein the light absorption layer has a thickness of about 0.1 micrometer to about 5 micrometers.

16. The method of claim 7, wherein the group I element is copper, the group III element is aluminum, gallium or indium, and the group VI element is sulfur, selenium or tellurium.

17. The thin film solar cell of claim 1, wherein the first light absorption layer comprises CuInSe₂, CuInS₂, CuGaSe₂ or CuInSe₂, the second light absorption layer comprises CuIn(Se₁₋ₓSₓ)₂, Cu(In_{1-y}Ga_{y})S₂, CuGa(Se₁₋ₓSₓ)₂, Cu(In_{1-y}Ga_{y})Se₂ or Cu(In_{1-y}Ga_{y})(Se₁₋ₓSₓ)₂, and the third light absorption layer comprises CuInS₂, CuGaS₂, or CuGaSe₂, in which x is 0 to 1 and y is 0 to 1.

18. The method of claim 9, wherein the first light absorption layer comprises CuInSe₂, CuInS₂, CuGaSe₂ or CuInSe₂, the second light absorption layer comprises CuIn(Se₁₋ₓSₓ)₂, Cu(In_{1-y}Ga_{y})S₂, CuGa(Se₁₋ₓSₓ)₂, Cu(In_{1-y}Ga_{y})Se₂ or Cu(In_{1-y}Ga_{y})(Se₁₋ₓSₓ)₂, and the third light absorption layer comprises CuInS₂, CuGaS₂, or CuGaSe₂, in which x is 0 to 1 and y is 0 to 1.
